(19) United States
(12) Patent Application Publication
(10) Pub. No.: US 2011/0233637 A1
(43) Pub. Date: Sep. 29, 2011

(54) SEMICONDUCTOR DEVICE AND METHOD FOR MANUFACTURING THE SAME

(76) Inventors: Tomoaki HATANO, Yokohama-shi (JP); Norihisa Arai, Saitama-shi (JP)

(21) Appl. No.: 13/052,156

(22) Filed: Mar. 21, 2011

(30) Foreign Application Priority Data
Mar. 23, 2010 (JP) 2010-066943

(51) Int. Cl. H01L 29/788; H01L 21/336

(52) U.S. Cl. 257/315; 438/257; 257/E21.422; 257/E29.3

(57) ABSTRACT

According to one embodiment, a method for manufacturing a semiconductor device comprises forming a first insulating film on a semiconductor substrate, processing the first insulating film into a predetermined pattern, forming a first gate electrode structure on the first insulating film, the first gate electrode structure having a smaller width than that of the processed first insulating film in a channel length direction, introducing a first impurity of a first conductivity type into the semiconductor substrate via the processed first insulting film using the first gate electrode structure as a mask, and introducing a second impurity of the first conductivity type into the semiconductor substrate using the first gate electrode structure and the first insulating film as a mask.

### CROSS-REFERENCE TO RELATED APPLICATIONS

This application is based upon and claims the benefit of priority from Japanese Patent Application No. 2010-066943, filed Mar. 23, 2010; the entire contents of which are incorporated herein by reference.

### FIELD

Embodiments described herein relate generally to a semiconductor device and a method for manufacturing the semiconductor device.

### BACKGROUND

In recent years, semiconductor devices have been increasingly miniaturized. Thus, formation of various transistors has been increasingly difficult.

For example, when a high-withstand-voltage transistor is formed, in the subsequent step, the gate insulating film may remain on a region of a semiconductor substrate in which impurities are diffused. When impurities are introduced into the semiconductor substrate with the gate insulating film thus remaining, an impurity diffusion layer is prevented from being formed under the gate insulating film. This may disadvantageously reduce a driving force for the high-withstand-voltage transistor.

A possible method for solving this problem uses ion implantation with an acceleration voltage increased when the impurities are introduced. However, this method may disadvantageously increase the depth of the impurity diffusion layer, reducing punch-through breakdown voltage.

Thus, formation of the high-withstand-voltage transistor requires a step of removing, by reactive ion etching (RIE), the gate insulating film remaining on the region in which the impurities are diffused. This results in an increase in the number of steps required. Thus, the conventional art does not always form high-withstand-voltage transistors efficiently.

A technique for increasing the driving force for a high-voltage transistor is disclosed in, for example, Jpn. Pat. Appln. KOKAI Publication No. 2002-76332.

### BRIEF DESCRIPTION OF THE DRAWINGS

FIG. 1A is a plan view schematically illustrating the basic configuration of a high-withstand-voltage P-type MOSFET according to an embodiment, FIG. 1B is a sectional view taken along line A-A in FIG. 1A, FIG. 1C is a plan view schematically illustrating the basic configuration of a memory cell transistor according to the embodiment, FIG. 1D is a sectional view taken along line C-C in FIG. 1C, FIG. 1E is a plan view schematically illustrating the basic configuration of a low-withstand-voltage P-type MOSFET according to the embodiment, and FIG. 1F is a sectional view taken along line E-E in FIG. 1E;

FIG. 2A is a plan view schematically illustrating a part of a basic method for manufacturing a high-withstand-voltage P-type MOSFET according to the embodiment, FIG. 2B is a sectional view taken along line A-A in FIG. 2A, FIG. 2C is a plan view schematically showing a part of a basic method for manufacturing a memory cell transistor according to the embodiment, FIG. 2D is a sectional view taken along line C-C in FIG. 2C, FIG. 2E is a plan view schematically illustrating a part of a basic method for manufacturing a low-withstand-voltage P-type MOSFET according to the embodiment, and FIG. 2F is sectional view taken along line E-E in FIG. 2E;

FIG. 3A is a plan view schematically illustrating a part of the basic method for manufacturing a high-withstand-voltage P-type MOSFET according to the embodiment, FIG. 3B is a sectional view taken along line A-A in FIG. 3A, FIG. 3C is a plan view schematically illustrating a part of the basic method for manufacturing a memory cell transistor according to the embodiment, FIG. 3D is a sectional view taken along line C-C in FIG. 3C, FIG. 3E is a plan view schematically illustrating a part of the basic method for manufacturing a low-withstand-voltage P-type MOSFET according to the embodiment, and FIG. 3F is a sectional view taken along line E-E in FIG. 3E;

FIG. 4A is a plan view schematically illustrating a part of the basic method for manufacturing a high-withstand-voltage P-type MOSFET according to the embodiment, FIG. 4B is a sectional view taken along line A-A in FIG. 4A, FIG. 4C is a plan view schematically illustrating a part of the basic method for manufacturing a memory cell transistor according to the embodiment, FIG. 4D is a sectional view taken along line C-C in FIG. 4C, FIG. 4E is a plan view schematically illustrating a part of the basic method for manufacturing a low-withstand-voltage P-type MOSFET according to the embodiment, and FIG. 4F is a sectional view taken along line E-E in FIG. 4E;

FIG. 5A is a plan view schematically illustrating a part of the basic method for manufacturing a high-withstand-voltage P-type MOSFET according to the embodiment, FIG. 5B is a sectional view taken along line A-A in FIG. 5A, FIG. 5C is a plan view schematically illustrating a part of the basic method for manufacturing a memory cell transistor according to the embodiment, FIG. 5D is a sectional view taken along line C-C in FIG. 5C, FIG. 5E is a plan view schematically illustrating a part of the basic method for manufacturing a low-withstand-voltage P-type MOSFET according to the embodiment, and FIG. 5F is a sectional view taken along line E-E in FIG. 5E;

FIG. 6A is a plan view schematically illustrating a part of the basic method for manufacturing a high-withstand-voltage P-type MOSFET according to the embodiment, FIG. 6B is a sectional view taken along line A-A in FIG. 6A, FIG. 6C is a plan view schematically illustrating a part of the basic method for manufacturing a memory cell transistor according to the embodiment, FIG. 6D is a sectional view taken along line C-C in FIG. 6C, FIG. 6E is a plan view schematically illustrating a part of the basic method for manufacturing a low-withstand-voltage P-type MOSFET according to the embodiment, and FIG. 6F is a sectional view taken along line E-E in FIG. 6E;

FIG. 7A is a plan view schematically illustrating a part of the basic method for manufacturing a high-withstand-voltage P-type MOSFET according to the embodiment, FIG. 7B is a sectional view taken along line A-A in FIG. 7A, FIG. 7C is a plan view schematically illustrating a part of the basic method for manufacturing a memory cell transistor according to the embodiment, FIG. 7D is a sectional view taken along line C-C in FIG. 7C, FIG. 7E is a plan view schematically illustrating a part of the basic method for manufacturing a low-withstand-voltage P-type MOSFET according to the embodiment, and FIG. 7F is a sectional view taken along line E-E in FIG. 7E;

FIG. 8A is a plan view schematically illustrating a part of the basic method for manufacturing a high-withstand-voltage P-type MOSFET according to the embodiment, FIG. 8B is a sectional view taken along line A-A in FIG. 8A, FIG. 8C is a plan view schematically illustrating a part of the basic method for manufacturing a memory cell transistor according to the embodiment, FIG. 8D is a sectional view taken along line C-C in FIG. 8C, FIG. 8E is a plan view schematically illustrating a part of the basic method for manufacturing a low-withstand-voltage P-type MOSFET according to the embodiment, and FIG. 8F is a sectional view taken along line E-E in FIG. 8E;

FIG. 9A is a plan view schematically illustrating a part of the basic method for manufacturing a high-withstand-voltage P-type MOSFET according to the embodiment, FIG. 9B is a sectional view taken along line A-A in FIG. 9A, FIG. 9C is a plan view schematically illustrating a part of the basic method for manufacturing a memory cell transistor according to the embodiment, FIG. 9D is a sectional view taken along line C-C in FIG. 9C, FIG. 9E is a plan view schematically illustrating a part of the basic method for manufacturing a low-withstand-voltage P-type MOSFET according to the embodiment, and FIG. 9F is a sectional view taken along line E-E in FIG. 9E;

FIG. 10A is a plan view schematically illustrating a part of the basic method for manufacturing a high-withstand-voltage P-type MOSFET according to the embodiment, FIG. 10B is a sectional view taken along line A-A in FIG. 10A, FIG. 10C is a plan view schematically illustrating a part of the basic method for manufacturing a memory cell transistor according to the embodiment, FIG. 10D is a sectional view taken along line C-C in FIG. 10C, FIG. 10E is a plan view schematically illustrating a part of the basic method for manufacturing a low-withstand-voltage P-type MOSFET according to the embodiment, and FIG. 10F is a sectional view taken along line E-E in FIG. 10E;

FIG. 11A is a plan view schematically illustrating a part of the basic method for manufacturing a high-withstand-voltage P-type MOSFET according to the embodiment, FIG. 11B is a sectional view taken along line A-A in FIG. 11A, FIG. 11C is a plan view schematically illustrating a part of the basic method for manufacturing a memory cell transistor according to the embodiment, FIG. 11D is a sectional view taken along line C-C in FIG. 11C, FIG. 11E is a plan view schematically illustrating a part of the basic method for manufacturing a low-withstand-voltage P-type MOSFET according to the embodiment, and FIG. 11F is a sectional view taken along line E-E in FIG. 11E;

FIG. 12 is a graph showing the relationship between the concentration of impurities and the distance over which impurities diffuse;

FIG. 13A is a plan view schematically illustrating the basic configuration of a high-withstand-voltage P-type MOSFET according to another example of embodiment, FIG. 13B is a sectional view taken along line A-A in FIG. 13A, FIG. 13C is a plan view schematically illustrating the basic configuration of a memory cell transistor according to the another example of embodiment, FIG. 13D is a sectional view taken along line C-C in FIG. 13C, FIG. 13E is a plan view schematically illustrating the basic configuration of a low-withstand-voltage P-type MOSFET according to the another example of embodiment, and FIG. 13F is a sectional view taken along line E-E in FIG. 13E; and

FIG. 14A is a plan view schematically illustrating the basic configuration of a high-withstand-voltage P-type MOSFET according to still another example of embodiment, FIG. 14B is a sectional view taken along line A-A in FIG. 14A, FIG. 14C is a plan view schematically illustrating the basic configuration of a memory cell transistor according to the still another example of embodiment, FIG. 14D is a sectional view taken along line C-C in FIG. 14C, FIG. 14E is a plan view schematically illustrating the basic configuration of a low-withstand-voltage P-type MOSFET according to the still another example of embodiment, and FIG. 14F is a sectional view taken along line E-E in FIG. 14E.

### DETAILED DESCRIPTION

In general, according to one embodiment, a method for manufacturing a semiconductor device comprises forming a first insulating film on a semiconductor substrate, processing the first insulating film into a predetermined pattern, forming a first gate electrode structure on the first insulating film, the first gate electrode structure having a smaller width than that of the processed first insulating film in a channel length direction, introducing a first impurity of a first conductivity type into the semiconductor substrate via the processed first insulting film using the first gate electrode structure as a mask, and introducing a second impurity of the first conductivity type into the semiconductor substrate using the first gate electrode structure and the first insulating film as a mask.

An embodiment will be described below in detail with reference to the drawings. In the embodiment described below, a NAND nonvolatile semiconductor memory device comprises a plurality of memory cell transistors connected together in series.

### Embodiment

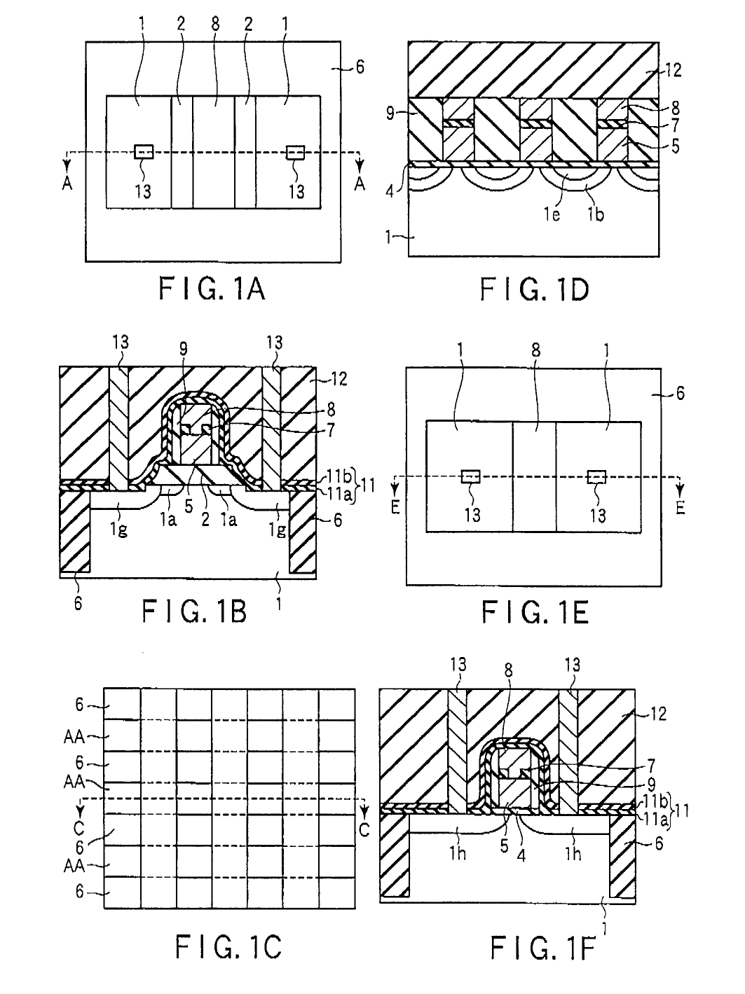

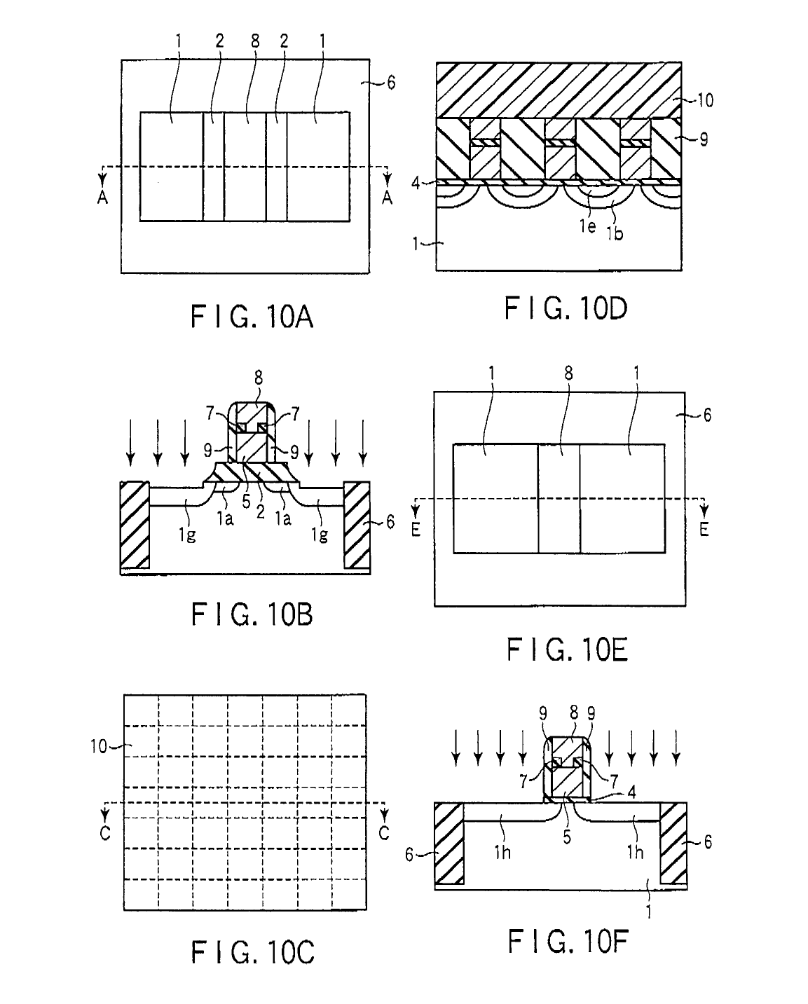

With reference to FIGS. 1A, 1B, 1C, 1D, 1E, and 1F, the basic configuration of a semiconductor device according to the present embodiment will be described in brief. FIG. 1A is a plan view of a high-withstand-voltage P-type metal oxide semiconductor field-effect transistor (MOSFET). FIG. 1B is a sectional view taken along line A-A in FIG. 1A. Furthermore, FIG. 1C is a plan view of a memory cell transistor. FIG. 10 is a sectional view taken along line C-C in FIG. 1C. Moreover, FIG. 1E is a plan view schematically illustrating the basic configuration of a low-withstand-voltage P-type MOSFET according to the embodiment. FIG. 1F is sectional view taken along line E-E in FIG. 1E.

As shown in FIGS. 1A and 1B, a pair of source/drain regions (first impurity diffusion regions) 1g in which P-type impurities are diffused are formed in a surface region of a semiconductor substrate (silicon substrate) 1 which is surrounded by a shallow trench isolation (STI) 6. Paired lightly doped drain (LDD) regions (second impurity diffusion regions) 1a are formed between the source/drain regions 1g; P-type impurities with a lower impurity concentration than the source/drain regions 1g are diffused in the LDD regions 1a. A channel region is sandwiched between the paired LDD regions 1a. Furthermore, for example, a silicon oxide film serving as a high-withstand-voltage (high-voltage) gate insulating film 2 with a film thickness of about 100 nm is formed on the LDD region 1a and the channel region. Here, the source/drain regions 1g are formed in a self-alignment manner with respect to the gate insulating film 2. In other words, the width of the gate insulating film 2 in a channel length direction is substantially equal to the total length, along a channel width direction, of the channel region and the paired LDD regions 1a between which the channel region is sandwiched. For example, polysilicon serving as an electrode film 5 is formed on the gate insulating film 2 and above the channel region. In addition, an electrode insulating film 7 is formed on a part of the electrode film 5. For example, polysilicon serving as an electrode film 8 is formed on a part of the electrode film 5 and on the insulating film 7. The electrode film 5 and the electrode film 8 are electrically connected together to function as a gate electrode. The gate electrode (gate electrode structure) has a smaller width than that of the gate insulating film 2 in the channel length direction. Furthermore, a sidewall film 9 covering the side surfaces of the electrode film 5, the insulating film 7, and the electrode film 8 is formed on the gate insulating film 2. Moreover, for example, a stack film of a silicon oxide film 11a and a silicon nitride film 11b serving as an insulating film (peripheral insulating film) 11 with a film thickness of about 10 nm is formed on the source/drain regions 1g. The insulating film 11 even covers the gate electrode structure and a part of the gate insulating film 2 which projects from the bottom of the gate electrode structure on the opposite sides of the gate electrode structure. The insulating film 11 has a film thickness less than that of the gate insulating film 2. The high-withstand-voltage P-type MOSFET is formed as described above, and an inter-layer insulating film 12 is further formed so as to cover the high-withstand-voltage P-type MOSFET. Conductive materials serving as contact portions (contact plugs) 13 are formed on the source/drain regions 1g and in the insulating film 11 and the interlayer insulating film 12. A part of the gate insulating film 2 which projects from the bottom of the gate electrode structure 3 contains, for example, boron (B) serving as P-type impurities and arsenic (As) serving as N-type impurities.

As shown in FIGS. 1C and 1D, source/drain regions (third impurity diffusion regions) 1e in which N-type impurities are diffused are formed in the surface region of the semiconductor substrate 1. A HALO region 1b in which P-type impurities are diffused is formed outside each of the source/drain regions 1e. Furthermore, a channel region is formed between the source/drain regions 1e. Additionally, a low-withstand-voltage gate insulating film 4 with a film thickness of about 8 nm is formed on the semiconductor substrate 1. For example, polysilicon serving as the electrode film 5, alumina serving as the inter-electrode insulating film 7, and polysilicon serving as the electrode film 8 are formed on the gate insulating film 4 and above the channel region in order; the electrode film 5 functions as a floating gate electrode (charge accumulation layer), and the electrode film 8 functions as a control gate electrode. A plurality of memory cell transistors are formed as described above. An inter-layer insulating film 9 used as a sidewall film in P-type MOSFETs is formed between memory cell transistors. Additionally, an interlayer insulating film 12 is formed on the memory cell transistor and the interlayer insulating film 9. Furthermore, a memory cell transistor formation region has a line and space (L/S) shape in which element regions AA and shallow trench isolations (isolation insulating films) 6 of the semiconductor substrate 1 are alternately formed.

As shown in FIGS. 1E and 1F, source/drain regions 1h in which P-type impurities are diffused are formed in the surface region of the semiconductor substrate 1 surrounded by the shallow trench isolations 6. A channel region is sandwiched between the paired the source/drain regions 1h. A low-withstand-voltage gate insulating film 4 with a film thickness of about 8 nm is formed on the channel region. An electrode film 5 is formed on the gate insulating film 4 and above the channel region. Furthermore, an insulating film 7 is formed on a part of the electrode film 5. An electrode film 8 is formed on a part of the electrode film 5 and on the insulating film 7. The electrode films 5 and 8 are electrically connected together to function as a gate electrode. Additionally, a sidewall film 9 covering side surfaces of the electrode film 5, the insulating film 7, and the electrode film 8 (gate electrode structure) is formed on the gate insulating film 4. Moreover, for example, a stack film of a silicon oxide film 11a and a silicon nitride film 11b serving as an insulating film 11 with a film thickness of about several nm is formed on the gate electrode structure and the source/drain regions 1h. A low-withstand-voltage P-type MOSFET is thus formed. Moreover, an interlayer insulating film 12 is formed so as to cover the low-withstand-voltage P-type MOSFET. Conductive materials serving as contact portions 13 are formed on the source/drain regions 1h and in the insulating film 11 and the interlayer insulating film 12.

According to the above-described embodiment, the insulating film 2 in the high-withstand-voltage P-type MOSFET has a greater width than that of the gate electrode (gate electrode structure) in the channel length direction. This improves the withstand voltage between the gate electrode and the semiconductor substrate 1. Furthermore, the LDD region 1a in which P-type impurities are diffused is formed in parts of the semiconductor substrate 1 which are located under the gate insulating film 2. This enables a decrease in a driving force for the P-type MOSFET to be suppressed. As a result, a high-quality semiconductor device with a high withstand voltage can be obtained.

Furthermore, the great width of the gate insulating film 2 allows the adverse effects of the insulating film 11 to be suppressed. That is, if the gate insulating film 2 has the same width as that of the gate electrode structure, charge is trapped in a part of the insulating film 11 which is located close to the substrate, thus affecting transistor characteristics. However, in the embodiment, the great width of the gate insulating film 2 serves to increase the distance between the insulating film 11 and the channel region. As a result, the above-described problems can be solved.

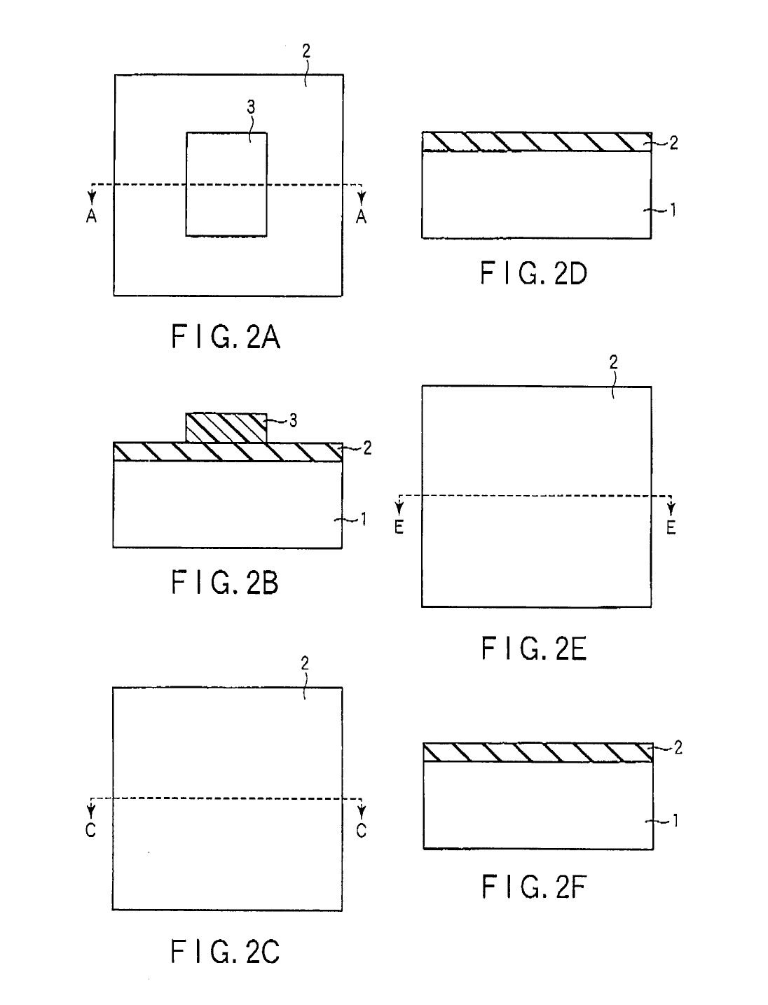

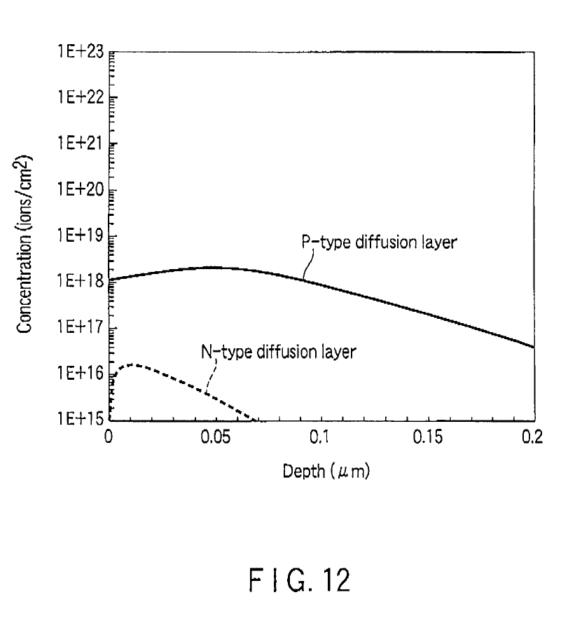

A basic method for manufacturing a semiconductor device according to the embodiment will be described in brief with reference to FIGS. 1A to 11A, FIGS. 1B to 11B, FIGS. 1C to 11C, FIGS. 1D to 11D, FIGS. 1E to 11E, FIGS. 1F to 11F, and FIG. 12. FIGS. 2A to 11A are plan views of a high-withstand-voltage P-type MOSFET formation region. Furthermore, FIGS. 2B to 11B are sectional views taken along line A-A in FIGS. 2A to 11A, respectively. FIGS. 2C to 11C are plan views of a memory cell transistor formation region. FIGS. 2D to 11D are sectional views taken along line C-C in FIGS. 2C to 11C, respectively. FIGS. 2E to 11E are plan views of a low-withstand-voltage P-type MOSFET formation region. FIGS. 2F to 11F are sectional views taken along line E-E in FIG. 2E to FIG. 11E. Additionally, FIG. 12 is a graph showing the relationship between the concentration of impurities and the distance over which the impurities diffuse.

First, as shown in FIGS. 2A, 2B, 2C, 2D, 2E, and 2F, for example, a silicon oxide film 2 serving as an insulating film with a thickness of about 100 nm is formed on the semiconductor substrate 1. A resist pattern 3 with a greater width than that of a gate electrode in the channel length direction to be formed during the subsequent step (the resist pattern 3 having a greater length along line A-A than that of the gate electrode) is formed on the insulating film 2 in the high-withstand-voltage P-type MOSFET formation region.

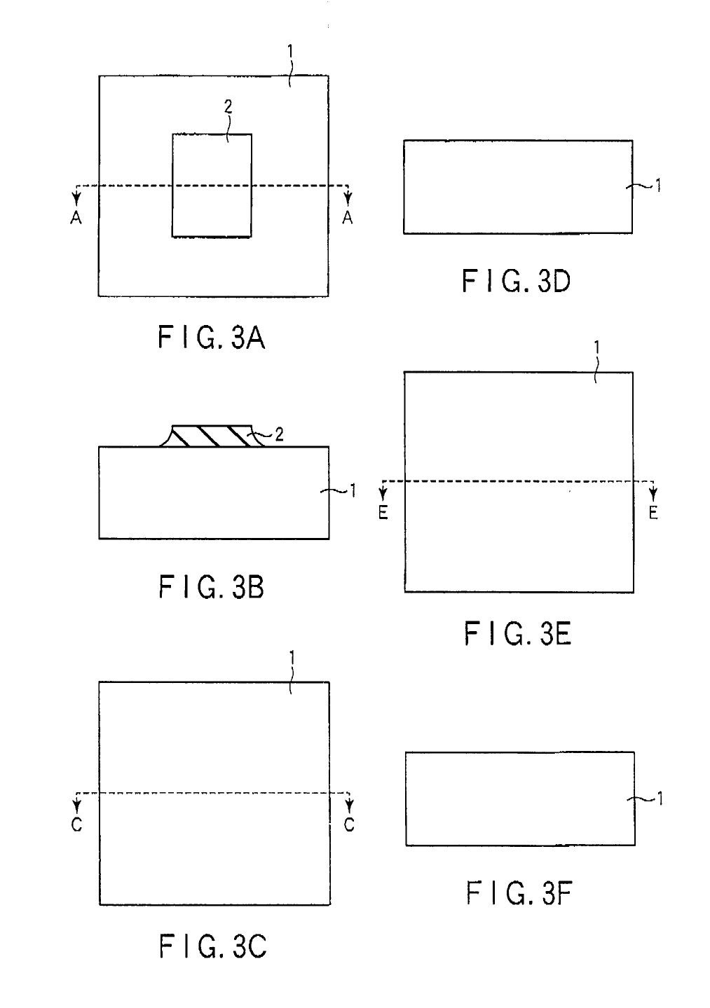

Then, as shown in FIGS. 3A, 3B, 3C, 3D, 3E, and 3F, wet etching is carried out through a resist pattern 3 as a mask to remove the insulating film 2 with a part of the insulating film 2 in the high-withstand-voltage P-type MOSFET formation region left. The wet etching is carried out such that the partly left insulating film 2 has a greater width, in the channel length direction, than that of the gate electrode to be formed in the subsequent step (the partly left insulating film 2 has a greater length along line A-A than that of the gate electrode).

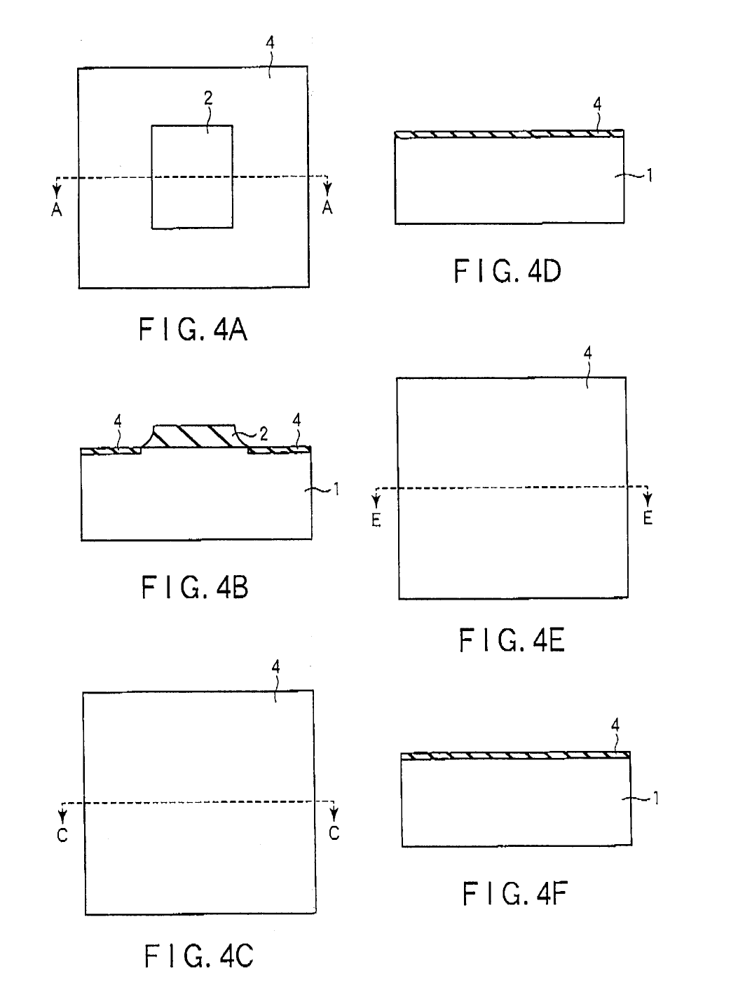

Then, as shown in FIGS. 4A, 4B, 4C, 4D, 4E, and 4F, for example, a thermal treatment is carried out to oxidize the surface of the semiconductor substrate 1. Thus, an insulating film 4 with a film thickness of about 8 nm is formed on the entire surface of the semiconductor substrate 1 except for a part of the substrate 1 on which the insulating film 2 is present.

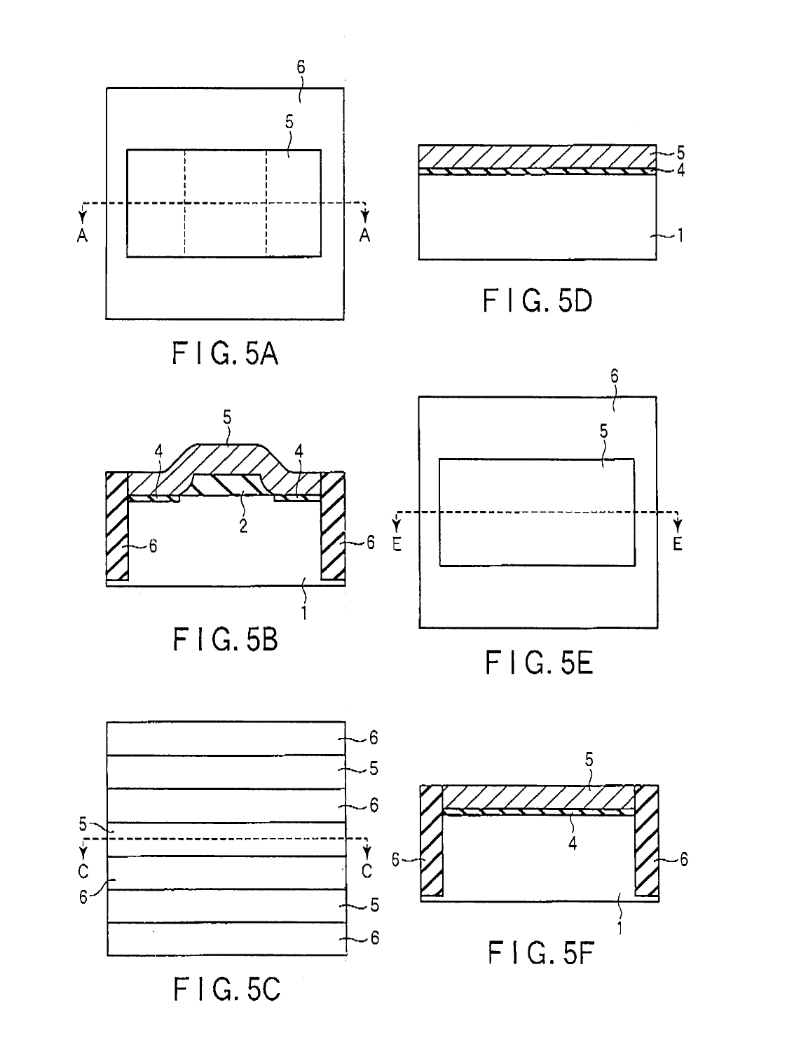

Then, as shown in FIGS. 5A, 5B, 5C, 5D, 5E, and 5F, for example, amorphous silicon 5 polycrystallized into a floating gate electrode during the subsequent thermal process is formed on the insulating film 2 and the insulating film 4. Then, a resist is formed on the amorphous silicon 5. More specifically, a resist pattern (not shown in the drawings) is formed corresponding to the gate electrode structure of the P-type MOSFET and semiconductor substrate 1 which has source/drain regions in the P-type MOSFET formation region and patterned into a line and space (L/S) shape with the resist extended in the direction in which memory cell transistors are arranged together in series in the memory cell transistor formation region. Then, anisotropic etching such as RIE is carried out through the resist pattern as a mask. Thus, the amorphous silicon 5, the insulating film 4, and the semiconductor substrate 1 are partly removed to form an STI trench in the semiconductor substrate 1, insulating film 4, and amorphous silicon 5. Then, a silicon oxide film serving as the shallow trench isolation 6 is buried in the trench. Thus a shallow trench isolation (shallow trench isolation film) 6 is formed in a region around the gate electrode structure of the P-type MOSFET and semiconductor substrate 1 which has source/drain region in the P-type MOSFET formation region and in a region along the direction in which memory cell transistors are arranged together in series in the memory cell transistor formation region.

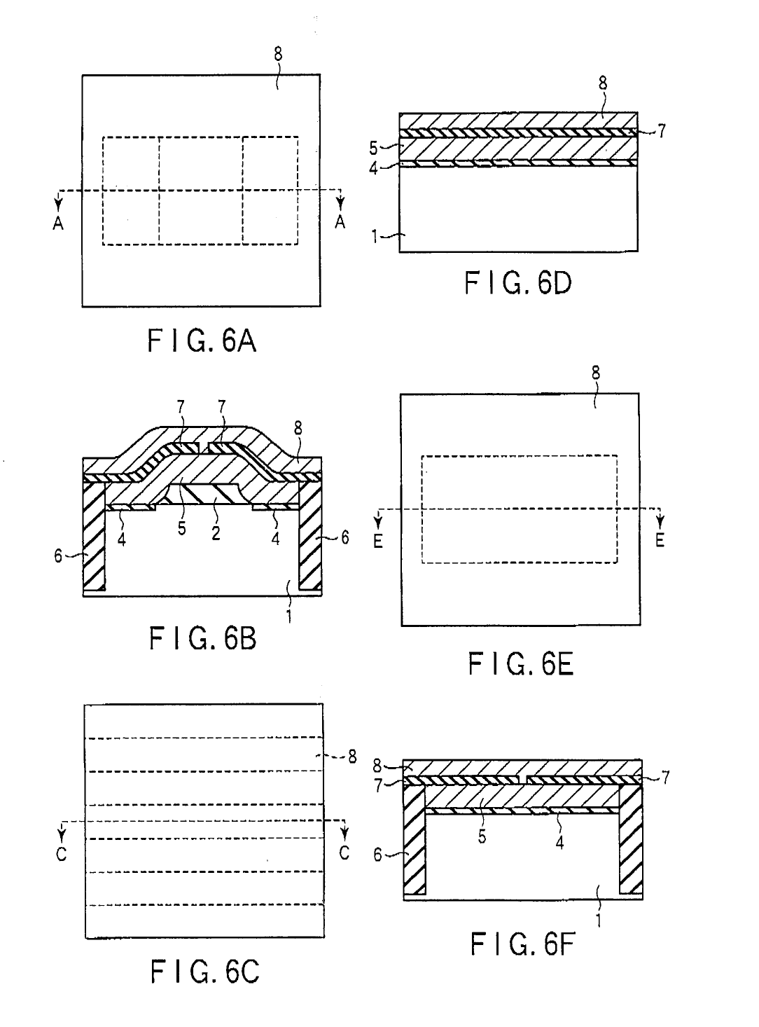

Then, as shown in FIGS. 6A, 6B, 6C 6D, 6E, and 6F, for example, alumina serving as an inter-electrode insulating film 7 is formed on the amorphous silicon 5 and the shallow trench isolation 6. For example, amorphous silicon 8 polycrystallized into a control gate electrode during the subsequent thermal process is formed on the inter-electrode insulating film 7. In the P-type MOSFET formation region, the insulating film 7 on the amorphous silicon 5 on which the gate electrode structure of the P-type MOSFET is formed is partly removed. Thus, a part of the amorphous silicon 5 on which the gate electrode structure of the P-type MOSFET is formed is in contact with the amorphous silicon 8.

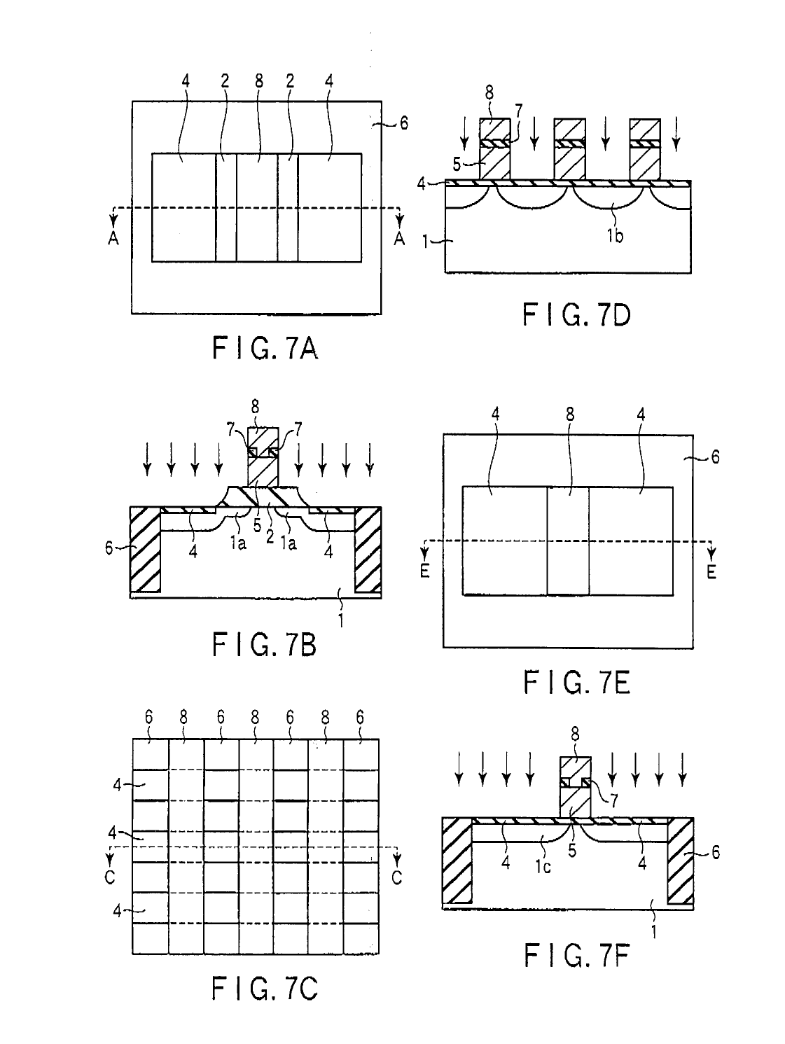

Then, as shown in FIGS. 7A, 7B, 7C, 7D, 7E, and 7F, a resist pattern (not shown in the drawings) is formed by lithography as a pattern on the gate electrode structure of the P-type MOSFET in the P-type MOSFET formation region and as a pattern on the gate electrode structures of the memory cell transistors in the memory cell transistor formation region. Anisotropic etching such as RIE is carried out through the resist pattern as a mask to pattern the amorphous silicon 8, the insulating film 7, and the amorphous silicon 5.

As described above, in the high-withstand-voltage P-type MOSFET formation region, the gate structure of the high-withstand-voltage P-type MOSFET is formed which comprises the electrode film 5, the insulating film 7 formed on a part of the electrode film 5, and the electrode film 8 formed on a part of the electrode film 5 and on the insulating film 7. Furthermore, the high-withstand-voltage gate insulating film 2 with a maximum film thickness of about 100 nm is formed under the electrode film 5 and near the region under the electrode film 5. In the other regions, an insulating film 4 with a film thickness of about 8 nm is formed.

Then, in the memory cell transistor formation region, a gate electrode structure in which the charge accumulation layer (floating gate electrode or electrode film) 5, the inter-electrode insulating film (for example, alumina) 7, and the control gate electrode (electrode film) 8 are stacked in order is formed on the gate insulating film (tunnel insulating film) 4.

Furthermore, in the low-withstand-voltage P-type MOSFET formation region, the gate electrode structure of the low-withstand-voltage P-type MOSFET is formed which includes the electrode film 5 formed on the gate insulating film 4, the insulating film 7 formed on a part of the electrode film 5, and the electrode film 8 formed on a part of the electrode film 5 and on the inter-electrode insulating film 7.

Subsequently, for example, boron (B) serving as P-type impurities and having a concentration of about 1E13 (ions/cm²) is introduced into the semiconductor substrate 1 by ion implantation through the obtained gate electrode structure as a mask. Here, as shown in FIG. 12, P-type impurities (particularly boron) have a greater Rp (project range) than that of N-type impurities. Thus, adjustment of concentration of the P-type impurities allows the P-type impurities to be introduced down to the semiconductor substrate 1 via the gate insulating film 2 with a thickness of about 100 nm. An LDD region 1a in which P-type impurities are introduced is formed in a part of the semiconductor substrate 1 which is located under the gate insulating film 2. At the same time, in the memory cell transistor formation region, P⁻ HALO regions 1b are formed around regions of the semiconductor substrate 1 which are each located below and between the gate electrode structures. Furthermore, in the low-withstand-voltage P-type MOSFET formation region, P-type impurity regions 1c are formed in parts of the semiconductor substrate 1 which are not covered with the gate structures.

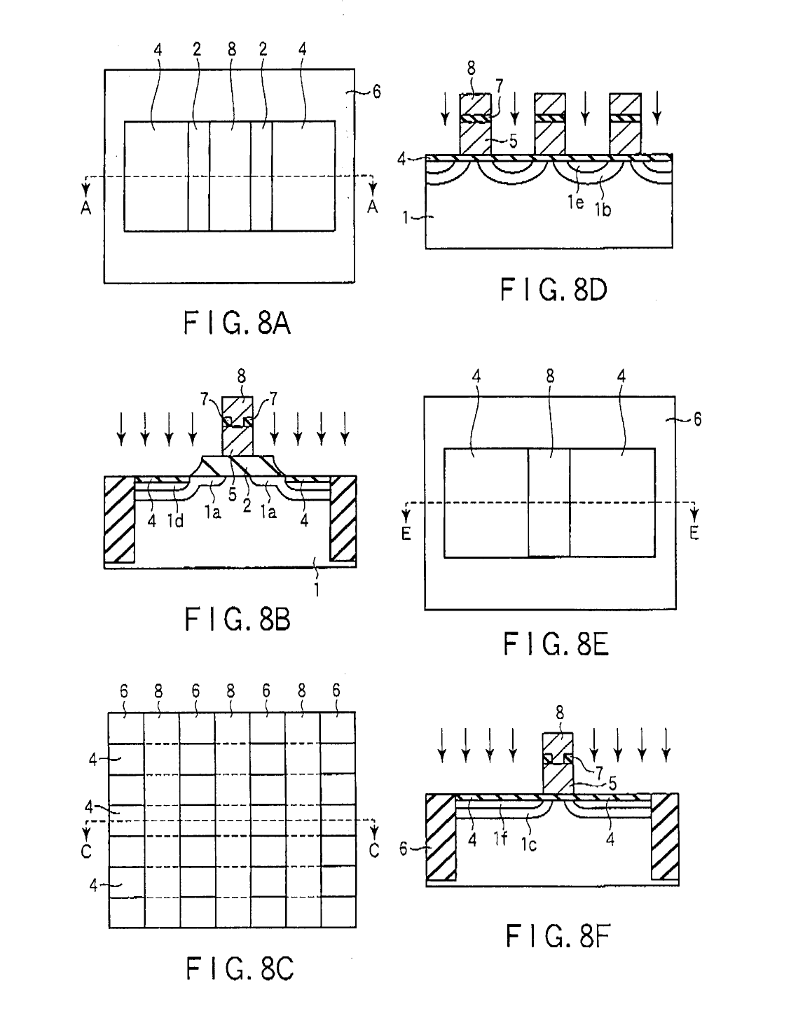

Then, as shown in FIGS. 8A, 8B, 8C, 8D, 8E, and 8F, arsenic (As) serving as N-type impurities and having, for example, a concentration of 1E13 (ions/cm²) is introduced into the semiconductor substrate 1. Here, as shown in FIG. 12, N-type impurities are not introduced deep into the substrate. Thus, in the high-withstand-voltage P-type MOSFET formation region, the N-type impurities are not introduced into parts of the semiconductor substrate 1 which are located under the gate insulating film 2, but remain in the gate insulating film 2. Furthermore, an N-type impurity region 1d is formed in parts of the semiconductor substrate 1 above which the gate insulating film 2 is not formed. At the same time, in the memory cell transistor formation region, N-type source/drain regions 1e are formed in regions of the semiconductor substrate 1 which are each located below and between the gate structures. Furthermore, in the low-withstand-voltage P-type MOSFET formation region, N-type impurity regions 1f are formed in parts of the semiconductor substrate 1 which are not covered with the gate electrode structures. In this case, N-type impurity regions are formed in the semiconductor substrate 1 in a surrounding N-type MOSFET formation region.

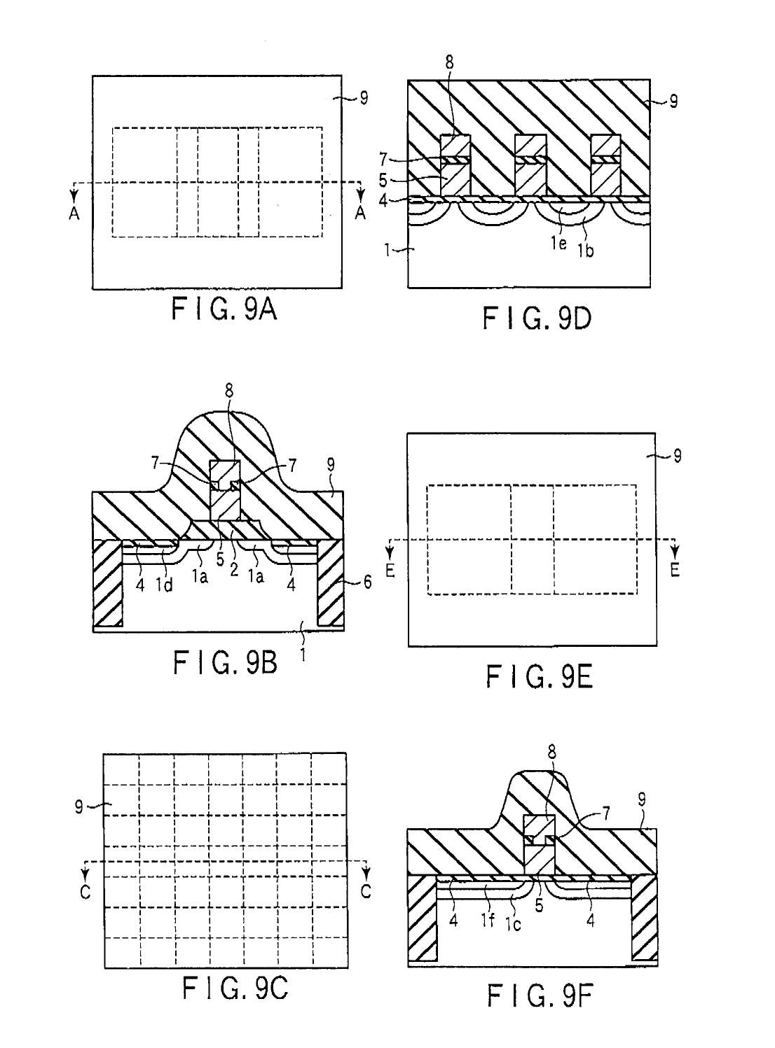

Then, as shown in FIGS. 9A, 9B, 9C, 9D, 9E, and 9F, for example, an insulating film (sidewall insulating film) 9 that is a silicon oxide film is deposited all over the resultant surface.

Then, as shown in FIGS. 10A, 10B, 10C, 10D, 10E, and 10F, the insulating film 9 is partly removed by RIE. At this time, each of the insulating film 4 and the shallow trench isolation 6 are partly removed. Thus, in the high-withstand-voltage P-type MOSFET formation region, the sidewall insulating film 9 is formed on the gate insulating film 2 and on the side surfaces of the electrode film 5, the insulating film 7, and the electrode film 8. Furthermore, in the memory cell transistor region, the insulating film 9 is buried between the gate electrode structures. Furthermore, in the low-withstand-voltage P-type MOSFET formation region, the sidewall insulating film 9 is formed on the gate insulating film 4 and on the side surfaces of the electrode 5, the insulating film 7, and the electrode film 8.

Then, in the memory cell transistor formation region, a mask 10 is formed on the gate electrode structure and the insulating film 9. Furthermore, at this time, an N-type MOSFET formation region (not shown in the drawings) is also covered with the mask 10. Boron fluoride (BF₂) serving as impurities and having a concentration of 1E15 (ions/cm²) is introduced into the P-type MOSFET formation region. Here, BF₂ is introduced at a low speed in order to suppress a short channel effect. In the high-withstand voltage P-type MOSFET formation region, the gate electrode structure and a part of the insulating film 2 which projects from the bottom of the gate electrode structure serve as a mask to cause BF₂ ions to remain in the projecting part of the gate insulating film 2. Then, a pair of P+ source/drain regions 1g between which the paired LDD regions 1a are sandwiched are formed in parts of the semiconductor substrate 1 in which the gate insulating film 2 is not formed. Furthermore, in the low-withstand-voltage P-type MOSFET formation region, a pair of P+ source/drain regions 1h are formed in a part of the semiconductor substrate 1 in which the gate electrode structure is not formed.

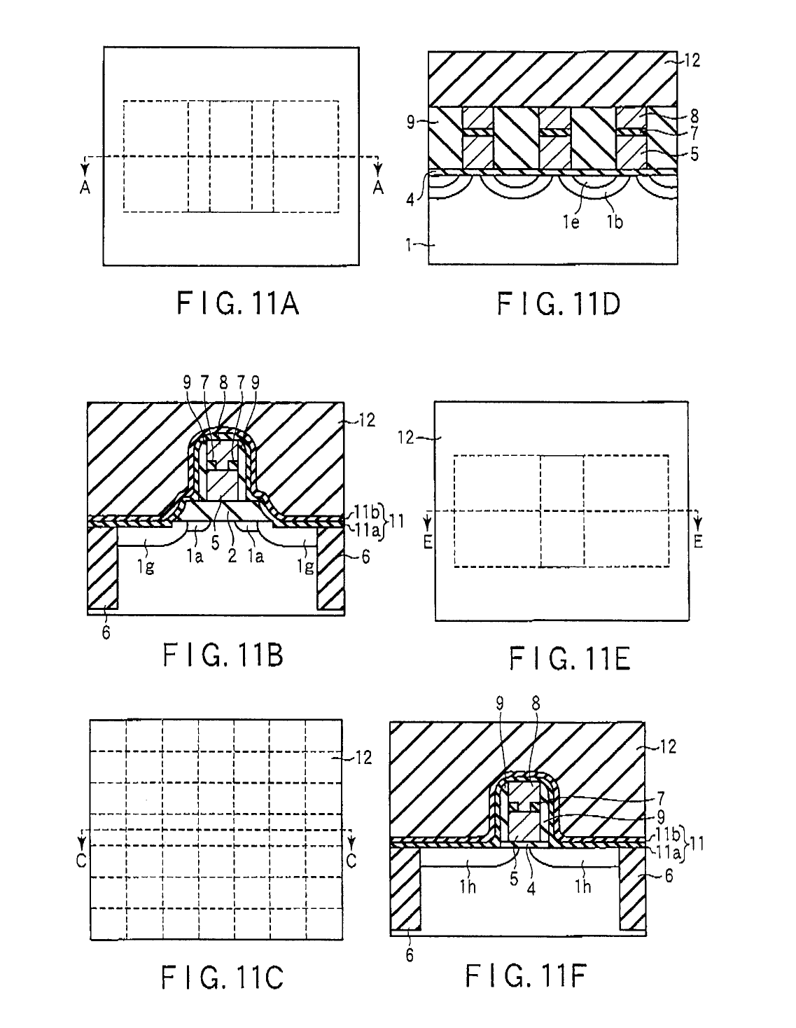

Then, as shown in FIGS. 11A, 11B, 11E, and 11F, a silicon oxide film (TEOS film) serving as an insulating film 11a and having a film thickness of about 5 nm is formed in the P-type MOSFET formation region. A silicon nitride film serving as an insulating film 11b and having a film thickness of about 5 nm is formed on the insulating film 11a. Thus, an insulating film (stopper film) 11 with the insulating films 11a and 11b is formed in the P-type MOSFET formation region. Then, a silicon oxide film serving as an interlayer insulating film 12 is formed on the stopper film 11. Furthermore, as shown in FIGS. 11C and 11D, in the memory cell transistor formation region, the mask 10 is removed, and the interlayer insulating film 12 is formed on the gate electrode structure and the insulating film 9.

Then, as shown in FIGS. 1A, 1B, 1E, and 1F, in the P-type MOSFET formation region, RIE is carried out through a resist (not shown in the drawings) as a mask to remove the interlayer insulating film 12 down to the stopper film 11. Moreover, parts of the stopper film 11 exposed at the bottom of removed interlayer insulating film 12 are removed to form holes for contact portions. A metal film for contact portions is filled in the holes to form contact portions 13.

Thereafter, a thermal treatment or the like is carried out to form a wiring layer and the like (not shown in the drawings) using a well-known technique. Hence, a nonvolatile semiconductor memory device is completed as shown in FIGS. 1A, 1B, 1C, 1D, 1E and 1F.

According to the above-described embodiment, the gate insulating film 2 of the high-withstand-voltage P-type MOSFET has a greater width than that of the gate electrode structure in the channel length direction. This enables the withstand voltage of the high-withstand-voltage P-type MOSFET to be improved. Furthermore, the great Rp of P-type impurities is utilized to introduce the impurities into the semiconductor substrate 1 via the thick gate insulating film 2. This allows LDD regions 1a with a lower impurity concentration than that of the source/drain regions 1g to be formed in a part of the semiconductor substrate 1 which is located under the gate insulating film 2. When the source/drain regions 1g are formed, the P-type impurities are introduced at a low speed and thus fail to reach the inside of the part of the semiconductor substrate 1 which is located under the gate insulating film 2. As a result, the LDD regions 1a can be adequately formed to allow a possible decrease in the driving force of the P-type MOSFET to be suppressed. The present method also allows the simultaneous formation of the LDD regions 1a in the high-withstand-voltage P-type MOSFET formation region and the HALO regions 1b in the memory cell transistor formation region. Thus, the manufacturing process can be simplified.

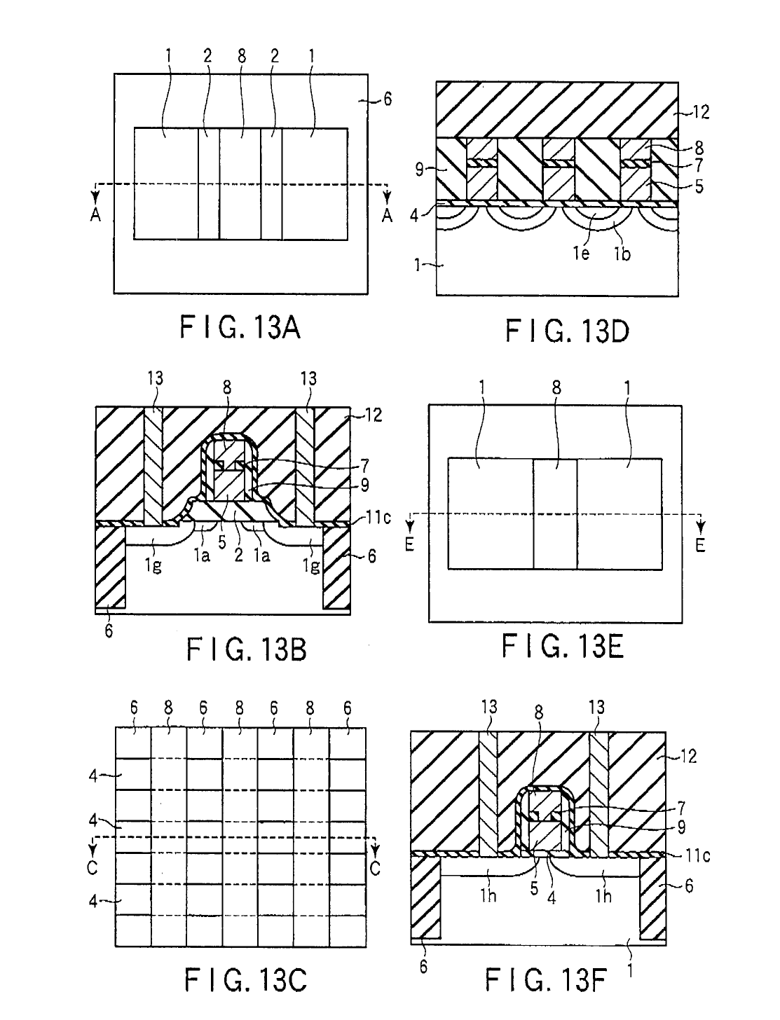

As shown in FIGS. 13A, 13B, 13C, 13D, 13E, and 13F, in a possible structure, the stopper film comprises only the silicon nitride film 11c with a film thickness of about 5 nm.

This structure is obtained by omitting, from the above-described manufacturing method, the step of forming the insulating film 11a shown in FIGS. 11A, 11B, 11E, and 11F.

As described above, if the silicon nitride film 11c is located at a short distance from a part of the semiconductor substrate 1 which lies below the gate electrode, charge trapped in the silicon nitride film 11c may cause the high-withstand-voltage P-type MOSFET to malfunction. In order to increase the distance between the semiconductor substrate 1, lying below the gate electrode, and the silicon nitride film 11c, a silicon oxide film may be formed under the silicon nitride film. However, in this structure, the gate insulating film 2 has a greater length than that of the gate electrode in a gate length direction. Thus, a sufficient distance is provided between the semiconductor substrate 1, lying below the gate electrode, and the silicon nitride film 11c, eliminating the need to form a silicon oxide film under the silicon nitride film 11c. This allows the step of forming the insulating film 11a to be omitted compared to the above-described embodiment. Furthermore, the film thickness of the insulating film formed between the contact portion 13 and the semiconductor substrate 1 can be reduced. This enables the simplified formation of a high-quality P-type MOSFET with a possible decrease in driving force suppressed.

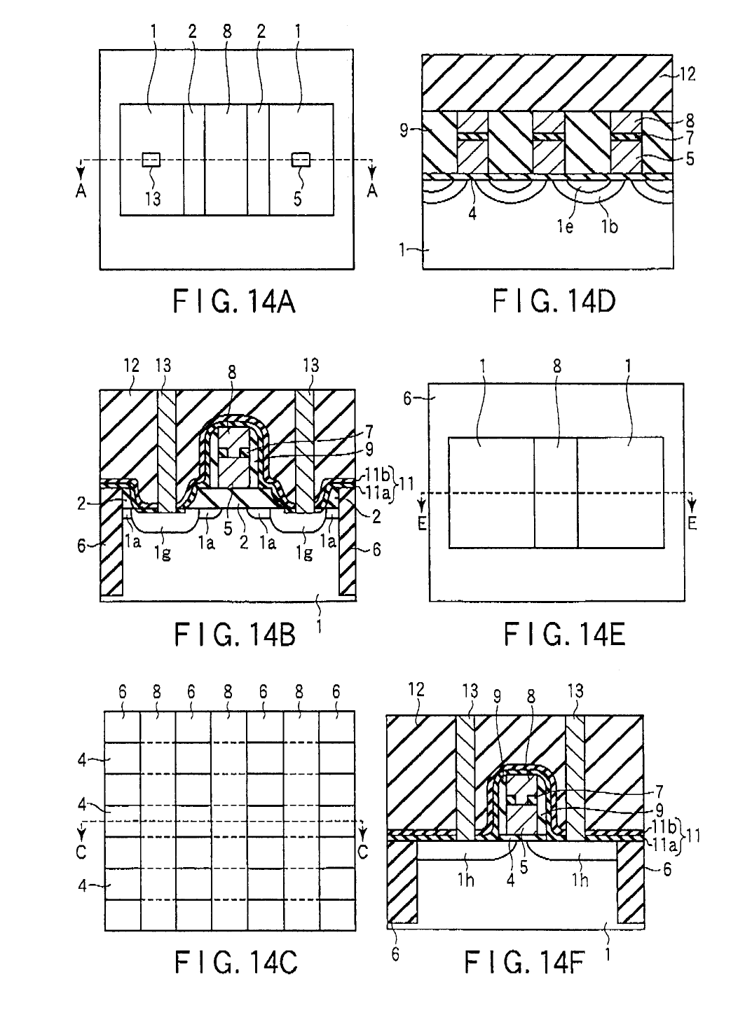

Furthermore, as shown in FIGS. 14A, 14B, 14C, 14D, 14E, and 14F, in a possible structure, the insulating film 2 with a film thickness of about 100 nm is formed on the semiconductor substrate 1 in the vicinity of the shallow trench isolations 6, and the LDD regions 1a are extended further into a part of the semiconductor substrate 1 which lies under the insulating film 2. In this structure, the source/drain regions 1g are surrounded by the regions 1a.

This structure is obtained as follows. In the above-described manufacturing method, when the resist pattern shown in FIGS. 2A and 2B is formed, the resist pattern is also formed in the vicinity of the regions in which shallow trench isolations are to be formed later. Then, during the wet etching illustrated in FIGS. 3A and 3B, the insulating film 2 is left in the vicinity of the regions in which shallow trench isolations are to be formed later.

This structure improves junction resistance because the P⁻ regions 1a are formed in the vicinity of the shallow trench isolations 6.

Furthermore, in the above-described embodiment, the width of the gate insulating film 2 along the channel length direction and the concentration and width of the LDD region 1a may be set for any conditions provided that the conditions allow the P-type MOSFET to enable switching. Furthermore, the LDD region can be controlled by varying the width of the gate insulating film 2 along the channel length direction.

Furthermore, in the above-described embodiment, each of the gate insulating film 2 and the insulating film 4 is preferably an oxide. However, the embodiment is not limited to this configuration. Additionally, in the above-described embodiment, a floating gate electrode (polysilicon) is used as the charge accumulation layer 5. However, a charge trapping insulating film (for example, a silicon nitride film) configured to hold charges may be used. In addition, alumina is used as the inter-electrode insulating film 7. However, any insulator that has a higher dielectric constant than silicon oxide may be used. Moreover, polysilicon is used as the electrode films 5 and 8 in the gate electrode structure. However, any substance that functions as the gate electrode may be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a semiconductor device, the method comprising:
forming a first insulating film on a semiconductor substrate;
processing the first insulating film into a predetermined pattern;
forming a first gate electrode structure on the first insulating film, the first gate electrode structure having a smaller width than that of the processed first insulating film in a channel length direction;
introducing a first impurity of a first conductivity type into the semiconductor substrate via the processed first insulting film using the first gate electrode structure as a mask; and
introducing a second impurity of the first conductivity type into the semiconductor substrate using the first gate electrode structure and the first insulating film as a mask.

2. The method according to claim 1, wherein the second impurity introduced into the semiconductor substrate has a greater concentration than that of the first impurity introduced into the semiconductor substrate.

3. The method according to claim 1, wherein the first conductivity type is a P type.

4. The method according to claim 1, wherein the first impurity is boron.

5. The method according to claim 1, wherein processing the first insulating film into the predetermined pattern comprises wet-etching the first insulating film.

6. The method according to claim 1, further comprising:
forming a second insulating film with a smaller film thickness than that of the first insulating film on the semiconductor substrate in a region in which the pattern of the first insulating film is not provided, after processing the first insulating film into the predetermined pattern; and
forming a second gate electrode structure on the second insulating film,
wherein introducing the first impurity comprises introducing the first impurity of the first conductivity type into the semiconductor substrate using the second gate electrode structure as a mask.

7. The method according to claim 6, further comprising:
introducing a third impurity of a second impurity type into the semiconductor substrate using the first gate electrode structure and the first insulating film as well as the second gate electrode structure as a mask.

8. The method according to claim 7, wherein the first conductivity type is a P type and the second conductivity type is an N type.

9. The method according to claim 6, wherein the second insulating film and the second gate electrode structure are included in a memory cell transistor.

10. The method according to claim 1, further comprising forming a third insulating film after introducing the second impurity into the semiconductor substrate, the third insulating film having a smaller film thickness than that of the first insulating film and covering the semiconductor substrate in which the second impurity has been introduced, the first gate electrode structure, and a part of the first insulating film which projects from the first gate electrode structure.

11. The method according to claim 10, wherein a third insulating film is a silicon nitride film.

12. The method according to claim 1, wherein the region in the semiconductor substrate in which the second impurity has been introduced is surrounded by a region in the semiconductor substrate in which the first impurity has been introduced.

13. The method according to claim 1, wherein introducing the second impurity comprises introducing the second impurity into the first insulating film.

14. A semiconductor device comprising:
paired first impurity diffusion regions of a P type formed in a surface region of a semiconductor substrate;
paired second impurity diffusion regions of a P type sandwiched between the paired first impurity diffusion regions and formed adjacent to the paired first impurity diffusion regions, the paired second impurity diffusion regions having a lower impurity concentration than that of the first impurity diffusion regions;
a channel region sandwiched between the paired second impurity diffusion regions;
a gate insulating film formed on the second impurity diffusion regions and on the channel region; and
a gate electrode formed on the gate insulating film and substantially immediately above the channel region and having a smaller width than that of the gate insulating film in a channel length direction, wherein the paired first impurity diffusion regions are formed in a self-aligned manner with respect to the gate insulating film.

15. The device according to claim 14, further comprising a peripheral insulating film formed on the first impurity diffusion regions as well as the gate electrode and a part of the gate insulating film which projects from the gate electrode, the gate insulating film having a greater film thickness than that of the peripheral insulating film.

16. The device according to claim 15, wherein the peripheral insulating film is a silicon nitride film.

17. The device according to claim 14, wherein the impurity contained in the second impurity diffusion regions is boron.

18. The device according to claim 14, wherein the first impurity diffusion regions are surrounded by the second impurity diffusion regions.

19. The device according to claim 14, wherein the gate insulating film contains a P-type impurity.

20. The device according to claim 14, further comprising a plurality of memory cell transistors and a low-withstand-voltage transistor formed on the semiconductor substrate,
wherein the gate insulating film has a greater film thickness than that of the memory cell transistors and the low-withstand-voltage transistor.
